(19) United States
(12) Patent Application Publication
(10) Pub. No.: US 2024/0412895 A1
(43) Pub. Date: Dec. 12, 2024

(54) SHIELDED ELECTRICAL CONDUCTOR WITH FOLDED SHIELDING LAYER

(71) Applicant: Aptiv Technologies Limited, St. Michael (BB)

(72) Inventors: Nathan UZARSKI, Warren, OH (US); Robert DEAN, New Castle, PA (US); David PETERSON, Aurora, OH (US); Joseph SUDIK, JR., Niles, OH (US); Marissa MAURY, Hubbard, OH (US); Stephen A. VANSUCH, Canfield, OH (US)

(21) Appl. No.: 18/208,005

(22) Filed: Jun. 9, 2023

(51) Int. Cl. H01B 7/08; H01B 7/02

(52) U.S. Cl. CPC H01B 7/0861; H01B 7/0258; H01B 7/0838

(57) ABSTRACT

A shielded conductor assembly includes an electrically conductive busbar having a width of the busbar that is greater than a thickness of the busbar and an inner insulative layer surrounding the busbar. The shielded conductor assembly also includes an electrically conductive foil shield layer having a longitudinal seam arranged substantially parallel to a longitudinal axis of the busbar and having a plurality of pleats arranged substantially parallel with one another surrounding the inner insulative layer. The shielded conductor assembly further includes an outer insulative layer surrounding the pleated foil shield layer. The plurality of pleats are configured to allow the busbar to be bent at an angle of at least 90 degrees along the thickness of the busbar without rupturing the foil shield layer. A method of manufacturing such a shielded conductor assembly is also provided.

### FIELD OF THE INVENTION

This patent application is directed to a shielded electrical conductor having folded shielding layer.

### BACKGROUND

High Voltage electrical cables are frequently shielded against electromagnetic interference (EMI) when used in automotive applications. The shielding is typically constructed of a plurality, e.g., 100-450, braided or woven tin-plated copper wire strands each having a small diameter, e.g., 40 American Wire Gauge (AWG). This type of shielding provides a high degree of cable flexibility. However, this shielding is expensive to incorporate into the cable and is difficult to process when terminating the cable. Specialized equipment is usually required to trim the shielding in order to attach a cable terminal.

U.S. Pat. No. 4,533,784 discloses a shielded ribbon cable conductor that includes a foil shield wrapped around the wire conductors in the ribbon cable. The foil is folded in pleats along a single plane and then wrapped around the cable. These pleats provide shield flexibility and tear resistance when the pleated foil shield is bent across the major width of the ribbon cable. It may be instantly recognized that this pleated foil shield is not well suited for being bent across the minor width, i.e., thickness, of the ribbon cable, because it is subject to tearing along the outer bend, i.e., the larger radius bend. Since this pleated foil shield is applied to a ribbon cable, this is not a concern since ribbon cables are also not well suited for being bent across the minor width.

However, other shielded electrical conductors having a major and minor width, such as rectangular shielded busbars, may be bent across the minor width or even twisted and are expected to maintain their shape and shielding properties after being bent. The single plane pleated shield of U.S. Pat. No. 4,533,784 has a higher risk of failure when being manipulated into these unique bend profiles.

Further, the single plane pleated shield of U.S. Pat. No. 4,533,784 requires application of an adhesive after wrapping the cable to keep the foil shield in place, thereby adding cost and complexity to the cable manufacturing process. Therefore, a foil shield suited for use with electrical conductors, including bent rectangular busbars that is simpler to manufacture remains desired.

### SUMMARY

According to one or more aspects of the present disclosure, a shielded conductor assembly includes an electrically conductive busbar having a width of the busbar that is greater than a thickness of the busbar and an inner insulative layer surrounding the busbar. The shielded conductor assembly also includes an electrically conductive foil shield layer having a longitudinal seam arranged substantially parallel to a longitudinal axis of the busbar and having a plurality of pleats arranged substantially parallel with one another surrounding the inner insulative layer. The shielded conductor assembly further includes an outer insulative layer surrounding the pleated foil shield layer. The plurality of pleats are configured to allow the busbar to be bent at an angle of at least 90 degrees along the thickness of the busbar without rupturing the foil shield layer.

In some aspects of the shielded conductor assembly described in the preceding paragraph, the plurality of pleats are arranged non-perpendicularly to the longitudinal axis across the width.

In some aspects of the shielded conductor assembly described in any one of the preceding paragraphs, the plurality of pleats are arranged perpendicularly to the longitudinal axis across the thickness.

In some aspects of the shielded conductor assembly described in any one of the preceding paragraphs, edges of the foil shield layer forming the seam overlap one another by 10 to 50%.

In some aspects of the shielded conductor assembly described in any one of the preceding paragraphs, edges of the foil shield layer forming the seam are crimped to have an overlapping and interlocked joint.

In some aspects of the shielded conductor assembly described in any one of the preceding paragraphs, the foil shield layer is formed of a copper-based material.

In some aspects of the shielded conductor assembly described in any one of the preceding paragraphs, the foil shield layer is formed of an aluminum-based material.

According to one or more aspects of the present disclosure, a method of manufacturing a shielded conductor assembly includes:
providing an electrically conductive busbar having a width of the busbar that is greater than a thickness of the busbar;
applying an inner insulative layer around the busbar;
wrapping an electrically conductive foil shield layer having a plurality of pleats arranged substantially parallel with one another around the inner insulative layer; thereby forming a longitudinal seam arranged substantially parallel to a longitudinal axis of the busbar, wherein the plurality of pleats are configured to allow the busbar to be bent at an angle of at least 90 degrees along the thickness of the busbar without rupturing the foil shield layer;
arranging the plurality of pleats non-perpendicularly to the longitudinal axis across the width; and
applying an outer insulative layer around the pleated foil shield layer.

In some aspects of the method described in the preceding paragraph, the method further includes arranging the plurality of pleats perpendicularly to the longitudinal axis across the thickness.

In some aspects of the method described in any one the preceding paragraphs, the method further includes overlapping edges of the foil shield layer forming the seam by 10 to 50%.

In some aspects of the method described in any one the preceding paragraphs, the method further includes crimping edges of the foil shield layer forming the seam to have an overlapping and interlocked joint.

In some aspects of the method described in any one the preceding paragraphs, the steps of applying the inner insulative layer around the busbar and applying the outer insulative layer around the pleated foil shield layer use one or more extrusion processes.

In some aspects of the method described in any one the preceding paragraphs, the foil shield layer is formed of a copper-based material.

In some aspects of the method described in any one the preceding paragraphs, the foil shield layer is formed of an aluminum-based material.

### DESCRIPTION OF THE DRAWINGS

The present invention is described, by way of example with reference to the accompanying drawing, in which:

FIG. 1 is an isometric view of a shielded electrical conductor showing the width and thickness according to some embodiments;

FIG. 2 is top view of the connector assembly of a pleated foil shield layer of the shielded electrical conductor of FIG. 1 according to some embodiments;

FIG. 3 is an isometric side cross section view of the shielded electrical conductor of FIG. 1 according to some embodiments;

FIG. 4 is an isometric view of the shielded electrical conductor of FIG. 1 bent along the thickness according to some embodiments; and

FIGS. 5A-5E are isometric views of steps of forming the shielded electrical conductor of FIG. 1 according to some embodiments;

FIG. 6 is a graph comparing shielding performance of various cable shield types; and

FIG. 7 is a flowchart of a method of manufacturing a shielded electrical conductor according to some embodiments.

### DETAILED DESCRIPTION

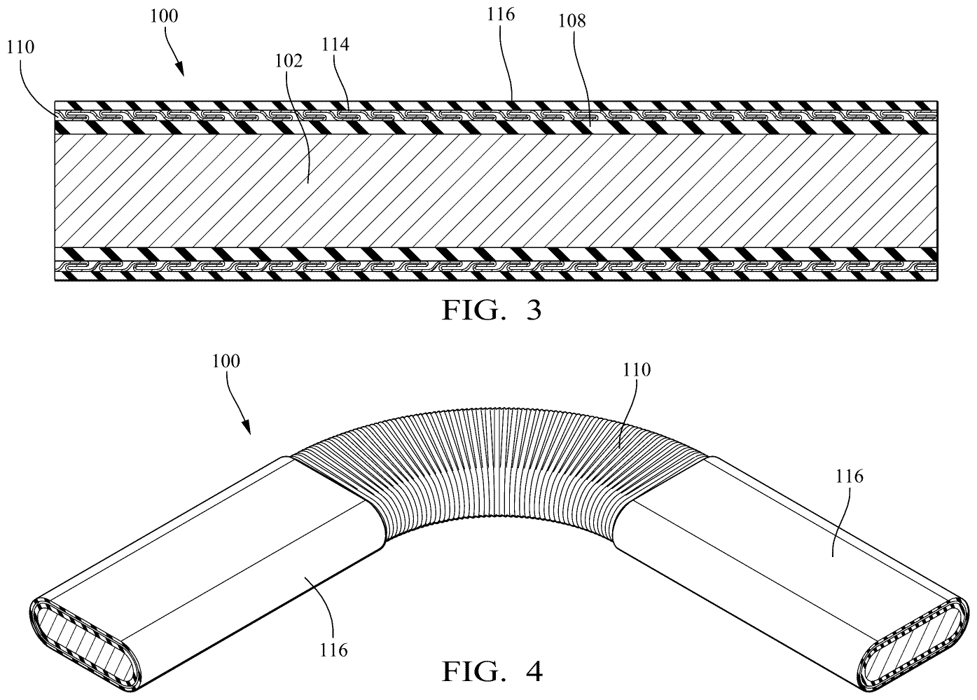

A non-limiting example of a shielded conductor assembly is shown in FIGS. 1-4. The shield conductor assembly, hereafter referred to as the assembly 100, includes a primary electrical conductor in the form of busbar 102 made of an electroconductive material, such as copper or aluminum. The busbar 102 has a width 104 which is greater than a thickness 106 of the busbar 102. In the illustrated example in FIGS. 1-5, the busbar 102 has a generally rectangular cross section. In alternative embodiments, the busbar 102 may have different cross sectional shapes meeting these width/thickness criteria, such as oval, trapezoidal, flattened hexagonal, etc. The busbar 102 is surrounded by an inner insulative layer 108 formed of a dielectric material, such as ethylene propylene diene monomer (EDPM) or silicone rubber. The inner insulative layer 108 is surrounded by a shield layer 110 that is configured to provide electromagnetic shielding for the primary electrical conductor against electromagnetic interference (EMI). This shield layer 110 is formed of an electroconductive foil, such as a copper-based or an aluminum-based foil which preferably has a thickness of 0.035 to 0.125 mm. The shield layer 110 has a longitudinal seam 112 arranged substantially parallel to a longitudinal axis X of the busbar. As used herein “substantially parallel” means±10° of being absolutely parallel. The shield layer 110 also forms a plurality of pleats 114 that are arranged substantially parallel to one another. The plurality of pleats 114 are configured to allow the busbar 102 to be bent at an angle of at least 90 degrees along the thickness 106 of the busbar 102 without rupturing the shield layer 110. An outer insulative layer 116 formed of a dielectric material surrounds the pleated shield layer 110. The outer insulative layer 116 may be formed of the same dielectric material as the inner insulative layer 108 or it may be formed of a different dielectric material because it does not have the same electrical breakdown requirements as the inner insulative layer. The dielectric material for the outer insulative layer 116 may instead be selected for providing abrasion and/or environmental contaminant resistance.

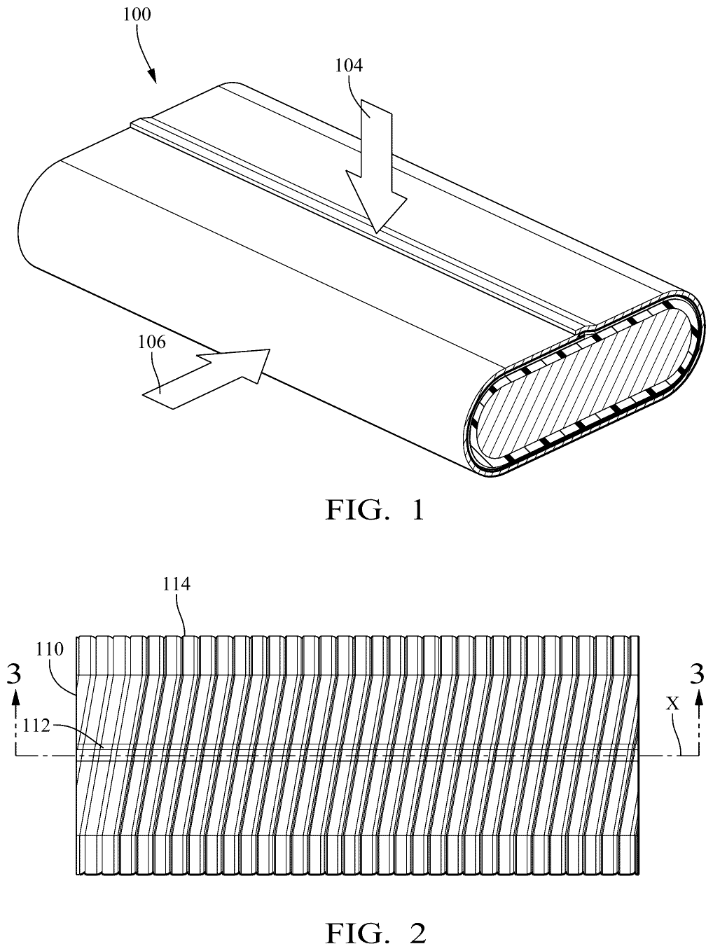

The plurality of pleats 114 are arranged non-perpendicularly to the longitudinal axis X across the width 104 of the busbar 102 and are arranged perpendicularly to the longitudinal axis X across the thickness 106 of the busbar 102 as best shown in FIG. 2. Therefore, the plurality of pleats 114 follow a non-spiral and non-helical path along the longitudinal axis X of the busbar 102. Inventors have found that this arrangement of the plurality of pleats 114 provides additional flexibility for the shield layer 110 when bending structures such as busbars that have a higher bending stiffness than braided cables or ribbon cables.

The edges of the shield layer 110 that form the seam 112 overlap one another by 10 to 50% and are crimped to one another with an overlapping and interlocked joint.

The plurality of pleats 114 have an undulating or wave-like shape along the longitudinal axis. A non-exhaustive list of wave like shapes may include a sinusoidal wave, a triangle wave, a square wave, a trapezoidal wave, and a sawtooth wave shape.

In the drawing of FIG. 4, the outer insulative layer 116 is cut away in a bent region so that the pleated shield layer 110 is visible. In actual use, the outer insulative layer 116 may also cover the pleated shield layer 110 in any bent region.

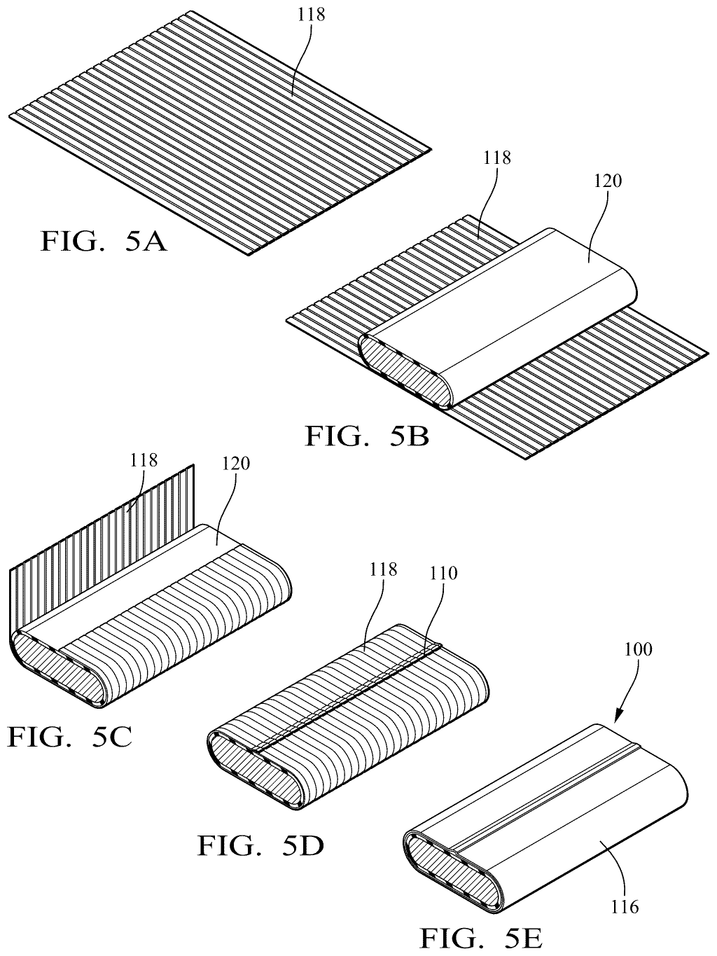

Selected steps of a method 200 of manufacturing the shielded conductor assembly 100 described above are illustrated in FIGS. 5A through 5E.

FIG. 5A shows a pleated sheet 118 formed of an electroconductive foil, such as a copper-based and/or aluminum-based foil which preferably has a thickness of 0.035 to 0.125 mm. As described above, the plurality of pleats 114 in the pleated sheet 118 have an undulating or wave-like shape.

FIG. 5B shows an insulated electrically conductive busbar 120. The insulated busbar 120 includes the busbar 102 surrounded by the inner insulative layer 108. The insulated busbar 120 is placed on the pleated sheet 118.

As shown in FIGS. 5C and 5D, the pleated sheet 118 is wrapped around the insulated busbar 120 to form a shield layer 110 having the longitudinal seam 112 arranged substantially parallel to a longitudinal axis X of the busbar 102. The edges of the pleated sheet 118 are overlapped and crimped. The plurality of pleats 114 are arranged so that they are angled relative to the longitudinal axis X, i.e., they are non-parallel to the longitudinal axis X and non-perpendicular to the longitudinal axis X across the width 104 of the busbar 102. In other words, the plurality of pleats 114 have an angle of inclination of the contact surface in an angular range of 1° to 89° and 91° to 179° relative to the longitudinal axis X across the width 104 of the busbar 102. The plurality of pleats 114 are arranged perpendicularly to the longitudinal axis X across the thickness 106 of the busbar 102 as shown in FIG. 2.

As shown in FIG. 5E, an outer insulative layer 116 is applied over the shield layer 110 to provide electrical insulation and environmental and/or abrasion protection for the resulting assembly 100.

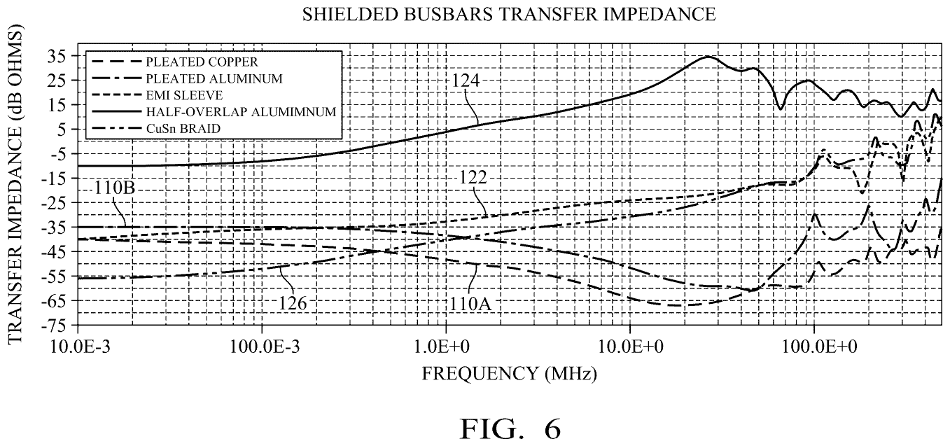

FIG. 6 is a graph comparing shielding performance of various cable shield types including a pleated shield layer 110A formed of copper, a pleated shield layer 110B formed of aluminum, and EMI sleeve 122, half overlapping aluminum tape 124, and tin-plated copper braided wire 126.

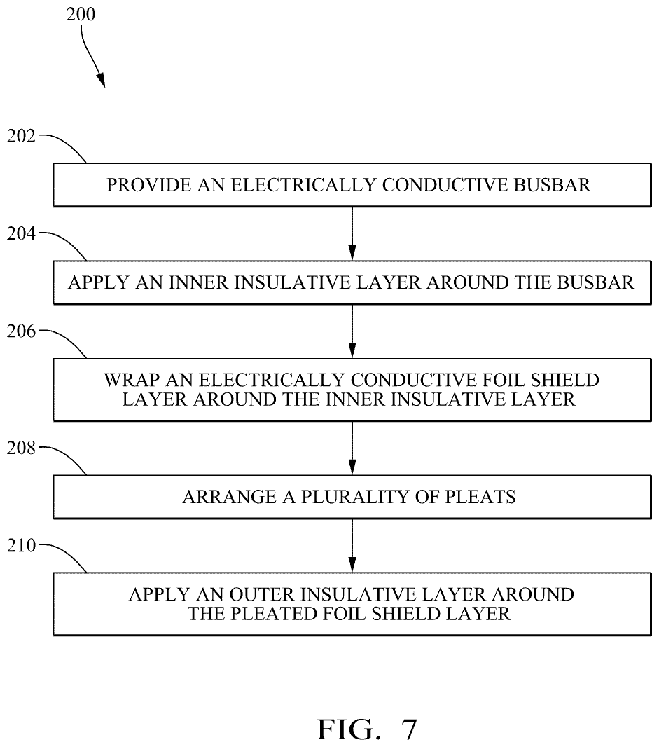

FIG. 7 shows a flow chart of the steps of the method 200 of manufacturing the shielded conductor assembly 100. The method 200 includes:

STEP 202, PROVIDE AN ELECTRICALLY CONDUCTIVE BUSBAR, includes providing an electrically conductive busbar 102 having a width 104 of the busbar 102 that is greater than a thickness 106 of the busbar 102;

STEP 204, APPLY AN INNER INSULATIVE LAYER AROUND THE BUSBAR, includes applying an inner insulative layer 108 around the busbar 102, thereby forming the insulated electrically conductive busbar 120;

STEP 206, WRAP AN ELECTRICALLY CONDUCTIVE FOIL SHIELD LAYER AROUND THE INNER INSULATIVE LAYER, includes wrapping an electrically conductive shield layer 110 having a plurality of pleats 114 arranged substantially parallel with one another around the inner insulative layer 108, thereby forming a longitudinal seam 112 arranged substantially parallel to a longitudinal axis X of the busbar 102. The shield layer 110 may be formed of a copper-based and/or an aluminum-based foil. The plurality of pleats 114 are configured to allow the busbar 102 to be bent at an angle of at least 90 degrees along the thickness 106 of the busbar 102 without rupturing the shield layer 110. STEP 206 may also include overlapping edges of the shield layer 110 forming the seam 112 by 10 to 50%;

STEP 208, ARRANGE A PLURALITY OF PLEATS, includes arranging the plurality of pleats 114 non-perpendicularly to the longitudinal axis X across the width 104 of the busbar 102. STEP 208 may also include arranging the plurality of pleats 114 perpendicularly to the longitudinal axis X across the thickness 106 of the busbar 102; and

STEP 210, APPLY AN OUTER INSULATIVE LAYER AROUND THE PLEATED FOIL SHIELD LAYER, includes applying an outer insulative layer 116 around the pleated shield layer 110.

STEPS 204 and 210 may use one or more extrusion processes.

While the invention has been described with reference to an exemplary embodiment(s), it will be understood by those skilled in the art that various changes may be made, and equivalents may be substituted for elements thereof without departing from the scope of the invention. In addition, many modifications may be made to adapt a particular situation or material to the teachings of the invention without departing from the essential scope thereof. Therefore, it is intended that the invention is not limited to the disclosed embodiment(s), but that the invention will include all embodiments falling within the scope of the appended claims.

As used herein, ‘one or more’ includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

Additionally, while terms of ordinance or orientation may be used herein these elements should not be limited by these terms. All terms of ordinance or orientation, unless stated otherwise, are used for purposes distinguishing one element from another, and do not denote any particular order, order of operations, direction or orientation unless stated otherwise.

1. A shielded conductor assembly, comprising:
an electrically conductive busbar having a width of the busbar that is greater than a thickness of the busbar;
an inner insulative layer surrounding the busbar;
an electrically conductive foil shield layer having a longitudinal seam arranged substantially parallel to a longitudinal axis of the busbar and having a plurality of pleats arranged substantially parallel with one another surrounding the inner insulative layer; and
an outer insulative layer surrounding the pleated foil shield layer, wherein the plurality of pleats are configured to allow the busbar to be bent at an angle of at least 90 degrees along the thickness of the busbar without rupturing the foil shield layer.

2. The shielded conductor assembly in accordance with claim 1, wherein the plurality of pleats are arranged non-perpendicularly to the longitudinal axis across the width.

3. The shielded conductor assembly in accordance with claim 2, wherein the plurality of pleats are arranged perpendicularly to the longitudinal axis across the thickness.

4. The shielded conductor assembly in accordance with claim 1, wherein edges of the foil shield layer forming the seam overlap one another by 10 to 50%.

5. The shielded conductor assembly in accordance with claim 1, wherein edges of the foil shield layer forming the seam are crimped to have an overlapping and interlocked joint.

6. The shielded conductor assembly in accordance with claim 1, wherein the foil shield layer is formed of a copper-based material.

7. The shielded conductor assembly in accordance with claim 1, wherein the foil shield layer is formed of an aluminum-based material.

8. A method of manufacturing a shielded conductor assembly, comprising:
providing an electrically conductive busbar having a width of the busbar that is greater than a thickness of the busbar;
applying an inner insulative layer around the busbar;
wrapping an electrically conductive foil shield layer having a plurality of pleats arranged substantially parallel with one another around the inner insulative layer; thereby forming a longitudinal seam arranged substantially parallel to a longitudinal axis of the busbar, wherein the plurality of pleats are configured to allow the busbar to be bent at an angle of at least 90 degrees along the thickness of the busbar without rupturing the foil shield layer;
arranging the plurality of pleats non-perpendicularly to the longitudinal axis across the width; and
applying an outer insulative layer around the pleated foil shield layer.

9. The method in accordance with claim 8, further comprising arranging the plurality of pleats perpendicularly to the longitudinal axis across the thickness.

10. The method in accordance with claim 8, further comprising overlapping edges of the foil shield layer forming the seam by 10 to 50%.

11. The method in accordance with claim 10, further comprising crimping edges of the foil shield layer forming the seam to have an overlapping and interlocked joint.

12. The method in accordance with claim 8, wherein the steps of applying the inner insulative layer around the busbar and applying the outer insulative layer around the pleated foil shield layer use one or more extrusion processes.

13. The method in accordance with claim 8, wherein the foil shield layer is formed of a copper-based material.

14. The method in accordance with claim 8, wherein the foil shield layer is formed of an aluminum-based material.
